(19) United States
(12) Patent Application Publication
(10) Pub. No.: US 2026/0107850 A1
(43) Pub. Date: Apr. 16, 2026

(54) Semiconductor Package Assembly

(71) Applicant: Microsoft Technology Licensing, LLC, Redmond, WA (US)

(72) Inventors: Ajay Singh Bist, Bengaluru (IN); Basavaraj Kanthi, Bengaluru (IN); Sateesh Selvakumar, Bengaluru (IN)

(21) Appl. No.: 18/916,090

(22) Filed: Oct. 15, 2024

(51) Int. Cl. H01L 23/498; H01L 23/00; H01L 23/538; H01L 25/18; H05K 1/18; H10B 80/00

(52) U.S. Cl. CPC H10W 90/401; H05K 1/181; H10W 70/611; H10W 70/65; H10W 90/701; H10B 80/00; H10W 90/00; H10W 90/724

(57) ABSTRACT

A semiconductor package assembly including: a package layer; an interposer layer electrically coupled to the package layer; and a compute die including one or more processing elements, wherein the compute die is electrically coupled to the interposer layer via one or more electrical connections positioned proximate the geometric center of the one or more processing elements.

### TECHNICAL FIELD

This disclosure relates to semiconductor package assemblies and, more particularly, to semiconductor package assemblies that reduce IR voltage drops.

### BACKGROUND

Voltage drops within integrated circuits (ICs) can significantly affect their performance and reliability. These drops occur primarily due to resistive losses in the power distribution network, where interconnects that distribute power have inherent resistance. As current flows through these resistive interconnects, it creates a voltage drop according to Ohm's Law (V=IR), leading to lower voltage at the far end of the interconnect. Additionally, current demand variations within an IC, such as during peak processing tasks, can cause larger voltage drops. Inductive effects in the power delivery network can also cause transient voltage drops due to changing current flows, particularly during rapid switching events in digital circuits. The combined voltage drop due to resistive and inductive elements, known as IR drop, further contributes to lower voltage reaching the active devices in the IC.

These voltage drops cause several performance problems. Timing errors arise because ICs, especially those operating at high speeds, rely on precise timing. Voltage drops can slow down transistor switching times, leading to logic errors and data corruption. Reduced noise margins make circuits more susceptible to electrical noise, causing incorrect logic states and malfunctions. Increased propagation delay results from lower supply voltage, degrading the performance of the IC by slowing down overall operation, which is critical in high-frequency applications. Transistors have a threshold voltage below which they do not turn on, and a reduced supply voltage can bring the operating voltage closer to this threshold, causing unreliable switching and increasing the likelihood of malfunction. While voltage drops can sometimes lead to lower power consumption, they can also cause certain parts of the circuit to draw more current to compensate, potentially leading to localized heating issues and affecting the reliability and lifespan of the IC. In severe cases, voltage drops can cause parts of the IC to fail to operate altogether, resulting in critical function failures and overall system instability.

### BRIEF DESCRIPTION OF THE DRAWINGS

FIG. 1 is a diagrammatic view of a semiconductor package assembly according to an embodiment of the present disclosure;

FIG. 2 is a diagrammatic view of a plurality of processing elements of the semiconductor package assembly of FIG. 1 according to an embodiment of the present disclosure;

FIGS. 3A-3B are diagrammatic views of the semiconductor package assembly of FIG. 1 according to an embodiment of the present disclosure; and

FIGS. 4A-4B are diagrammatic views of an implementation of clock phases on the semiconductor package assembly of FIG. 1 according to an embodiment of the present disclosure.

Like reference symbols in the various drawings indicate like elements.

### DETAILED DESCRIPTION OF THE PREFERRED EMBODIMENTS

As discussed above, voltage drops within integrated circuits (ICs) can significantly affect their performance and reliability, wherein these drops occur primarily due to resistive losses in the power distribution network, in that the interconnects that distribute power have inherent resistance.

As will be discussed below in greater detail, implementations of the present disclosure concern a semiconductor package assembly that includes: a package layer; an interposer layer electrically coupled to the package layer; and a compute die including one or more processing elements, wherein the compute die is electrically coupled to the interposer layer via one or more electrical connections positioned proximate the geometric center of the one or more processing elements. By positioning these electrical connections proximate the geometric center of the processing elements, IR losses within the semiconductor package assembly may be managed and equalized.

### Semiconductor Package Assembly

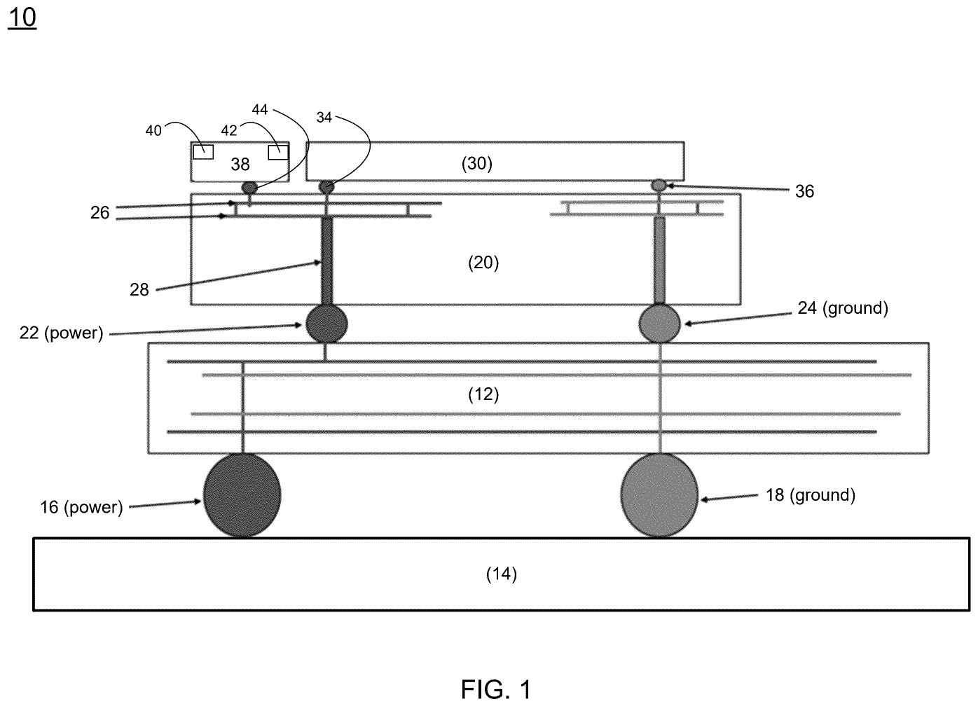

Referring to FIG. 1, there is shown a semiconductor package assembly (e.g., semiconductor package assembly 10). The semiconductor package assembly (e.g., semiconductor package assembly 10) may refer to a single integrated circuit assembly that encapsulates most or all of the components of a computer or electronic system into a single assembly. These components may include processing, memory, input interfaces, output interfaces, and various other subsystems (depending upon the intended application).

The semiconductor package assembly (e.g., semiconductor package assembly 10) may include a package layer (e.g., package layer 12). In the context of the semiconductor package assembly (e.g., semiconductor package assembly 10), a package layer (e.g., package layer 12) may refer to a distinct level or strata within the package assembly (e.g., semiconductor package assembly 10) that contributes to its structural integrity, protection, and functionality.

The package layer (e.g., package layer 12) may be configured to be electrically coupled to a system board (e.g., system board 14).

A system board (e.g., system board 14), also known as a motherboard or mainboard, is the primary circuit board in a computer system. It may serve as the central hub connecting various components such as the CPU (Central Processing Unit), memory modules, storage devices, expansion cards, and peripherals. The system board (e.g., system board 14) may provide the electrical connections and pathways that allow these components to communicate with each other and work together to execute tasks and run software.

For example, the package layer (e.g., package layer 12) may be electrically coupled to the system board (e.g., system board 14) using one or more package balls (e.g., package balls 16, 18). In the context of silicon package assemblies, package balls (e.g., package balls 16, 18) refer to the small solder balls or bumps located on the underside of the semiconductor package assembly (e.g., semiconductor package assembly 10). These balls may serve as the electrical connections between the semiconductor package assembly (e.g., semiconductor package assembly 10) and the system board (e.g., system board 14). The package balls (e.g., package balls 16, 18) may be made of a solder material, such as tin-lead or lead-free solder, and may be arranged in a specific pattern corresponding to the layout of the electrical contacts on the semiconductor package assembly (e.g., semiconductor package assembly 10). When the semiconductor package assembly (e.g., semiconductor package assembly 10) is mounted onto the system board (e.g., system board 14), the package balls (e.g., package balls 16, 18) may align with corresponding pads on the system board (e.g., system board 14). And through a process called reflow soldering, heat may be applied to melt the solder balls (e.g., package balls 16, 18), creating a permanent electrical connection between the semiconductor package assembly (e.g., semiconductor package assembly 10) and the system board (e.g., system board 14).

The semiconductor package assembly (e.g., semiconductor package assembly 10) may include an interposer layer (e.g., interposer layer 20) electrically coupled to the package layer (e.g., package layer 12).

An Interposer Layer (e.g., interposer layer 20) in a semiconductor package assembly (e.g., semiconductor package assembly 10) may be a crucial intermediary component used primarily in sophisticated semiconductor packaging technologies like 2.5D and 3D IC packaging. It may serve to bridge the physical and electrical gap between the silicon die (or dies) and the substrate or main package board. The primary function of the interposer may be to facilitate dense and complex electrical connections that may otherwise be unachievable with traditional packaging methods such as wire bonding or flip-chip techniques. As will be discussed below, this may be accomplished by providing a dense network of electrical pathways, often through the use of Through-Silicon Vias (TSVs), which connect the contacts on the die to corresponding pads on the substrate. Interposers may not only improve the electrical interconnection but may also enhance signal integrity and performance by reducing the transmission distances and the resistive and capacitive load of the connections. This enhancement may be critical for applications requiring high-speed data processing and minimal latency, such as in high-performance computing environments. Additionally, interposers may play a role in thermal management by incorporating materials or designs that help dissipate heat away from the silicon dies, thereby maintaining optimal operating temperatures and mechanical support to the structure. They may also help manage and distribute mechanical stress caused by thermal expansion or other forces, ensuring the longevity and reliability of the semiconductor package. The materials used for interposers may vary, including silicon, which is most common due to its compatibility with semiconductor processes; glass, chosen for its excellent electrical insulation properties; and organic materials, which are less costly and offer flexibility in matching thermal expansion coefficients with different substrates.

The interposer layer (e.g., interposer layer 20) may be electrically coupled to the package layer (e.g., package layer 12) via one or more electrical connections positioned proximate the geometric center (to be discussed below in greater detail) of one or more portions of the interposer layer (e.g., interposer layer 20). These electrical connections may include: one or more power connections and one or more ground connections. For example, interposer layer (e.g., interposer layer 20) may be electrically coupled to package layer (e.g., package layer 12) using one or more C4 bumps (e.g., C4 bumps 22, 24).

A C4 Bump (e.g., C4 bumps 22, 24), namely a Controlled Collapse Chip Connection, is a type of solder bump used in microelectronic packaging to connect semiconductor chips to substrates or other components in a package assembly. C4 bumps may be made of a solder material, such as a eutectic alloy of tin and lead or lead-free alternatives like tin-silver-copper (SnAgCu). C4 bumps are called “controlled collapse” because during the assembly process, the solder is initially deposited as a ball on the chip's bonding pads. Then, through controlled heating, the solder undergoes a phase change from solid to liquid, collapsing under surface tension and forming a stable, reliable connection between the chip and the substrate. C4 bumps (e.g., C4 bumps 22, 24) may be used in flip-chip technology, where the semiconductor chip is flipped upside down and attached directly to the substrate or package. This configuration may offer advantages such as shorter signal paths, better thermal performance, and higher interconnect density compared to traditional wire bonding techniques.

The interposer layer may include\: one or more interposer ReDistribution Layers (e.g., interposer ReDistribution Layers 26) and one or more Through Silicon Vias (e.g., Through Silicon Vias 28) to distribute power to a compute die (e.g., computer die 30).

An Interposer Redistribution Layer (RDL) may be integral to advanced semiconductor packaging technologies. An interposer acts as an intermediary layer or substrate placed between the semiconductor die and the printed circuit board (PCB). The primary function of RDLs may be to enhance routing flexibility, allowing signal paths to be re-routed to match the interposer or PCB connection points. This capability may be particularly useful for high pin-count devices or complex interconnections. RDLs may be fabricated using thin-film metallization processes and photolithography and may enable higher interconnect density, shorter signal paths, and improved electrical performance. Overall, the combination of interposers and RDLs may facilitate advanced packaging solutions such as 2.5D and 3D ICs, where multiple dies or components are stacked or placed side by side.

A Through-Silicon Via (TSV) is a vertical electrical connection that passes through a silicon wafer or die, facilitating the direct stacking of multiple semiconductor dies in a three-dimensional (3D) integrated circuit (IC) structure. TSVs may be crucial for creating high-density, high-performance chip packages by providing efficient vertical interconnections between the different layers of stacked dies. The structure of a TSV may involve cylindrical holes that are etched through the silicon substrate and filled with a conductive material such as copper or tungsten. The fabrication process typically may include etching the vias into the silicon, insulating the via walls with a dielectric material, filling the vias with metal, and planarizing the surface to ensure a flat and smooth finish. The primary function of TSVs may be to enable electrical signals and power to be transmitted vertically between stacked dies, reducing the distance that signals must travel. This reduction in distance may improve signal speed and overall performance while also enhancing power efficiency. TSVs may allow for a higher degree of integration and miniaturization, making them essential for advanced semiconductor technologies such as 3D ICs, where multiple dies or components are vertically stacked. The use of TSVs may result in shorter interconnect lengths, lower resistance and inductance, and improved thermal management, which are critical factors for the performance and reliability of modern electronic devices.

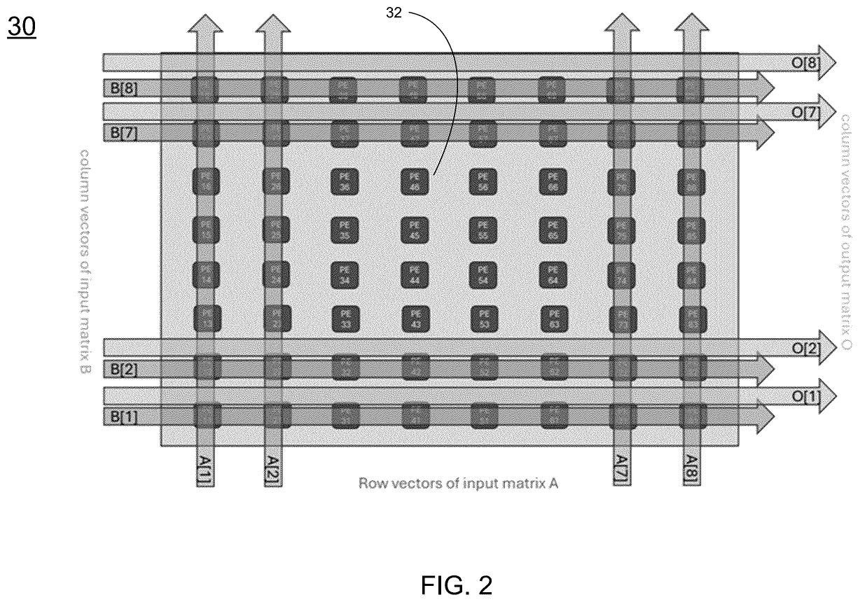

Referring also to FIG. 2, the semiconductor package assembly (e.g., semiconductor package assembly 10) may include a compute die (e.g., compute die 30) including one or more processing elements (e.g., processing elements 32).

A Compute Die in a semiconductor assembly may refer to a specialized piece of silicon within an integrated circuit (IC) or system-on-chip (SoC) dedicated to processing and computational tasks. The compute die may house core processing units such as the central processing unit (CPU), graphics processing unit (GPU), or other specialized processors like neural processing units (NPUs) for AI and machine learning tasks. The compute die may include processing cores, caches, and other components essential for executing instructions and computational tasks, and it may also contain the memory controller and interface units for communication with other system parts. In modern semiconductor designs, multiple dies may be integrated within a single package, and the compute die may be a key part of this multi-die configuration, working alongside memory dies, I/O dies, and fabric dies that handle interconnects. The compute die may be crucial for the performance of the semiconductor assembly as it handles the primary computational load, with its architecture, core count, clock speed, and efficiency directly impacting the system's overall processing power. Depending on the application, the compute die may be specialized, with CPUs focusing on general-purpose computing, GPUs accelerating graphics and parallel processing tasks, and NPUs optimizing AI computations. Isolating computational tasks to a dedicated compute die allows for optimized power consumption and thermal management, enhancing the performance per watt of the die. Additionally, this modular approach may allow for scalability, as adding more compute dies can enhance processing capabilities without redesigning the entire chip, which may be beneficial in data centers and high-performance computing environments.

As discussed above, the compute die (e.g., compute die 30) may include one or more processing elements (e.g., processing elements 32) Processing Elements within a computer die may be the fundamental units responsible for executing instructions and performing computations. These elements may include the central processing units (CPUs) or cores, which handle general-purpose tasks and arithmetic operations. Additionally, they may encompass specialized units such as arithmetic logic units (ALUs) that perform mathematical calculations, floating-point units (FPUs) for handling complex numerical computations, and vector processing units (VPUs) that manage data parallelism for tasks like multimedia processing. Processing elements may consist of control units that direct the operation of the processor, managing the sequencing and execution of instructions. Furthermore, they may include various types of caches (L1, L2, and sometimes L3) that store frequently accessed data to reduce latency and speed up processing. These elements may be interconnected through a sophisticated network of buses and interconnects, ensuring efficient data flow and communication within the die.

Examples of the one or more processing elements (e.g., processing elements 32) may include but are not limited to one or more matrix multipliers.

A Matrix Multiplier within a computer die is a specialized hardware unit designed specifically to perform matrix multiplication operations, which may be crucial in many computational fields like computer graphics, scientific computing, and machine learning. These units may enhance performance by executing multiple arithmetic operations in parallel, exploiting the inherent parallelism of matrix multiplication tasks. Unlike general-purpose CPUs, which handle a wide range of computations, matrix multipliers may focus on optimizing and accelerating matrix-related operations, allowing them to deliver results much faster and more efficiently. This parallel processing capability may not only speed up computation but may also improve the overall system throughput by freeing the CPU to perform other tasks. Additionally, these specialized units may be more power-efficient than their general-purpose counterparts, particularly beneficial in power-sensitive applications. Matrix multipliers may be integrated into various forms within a computer die, including as part of GPUs (Graphics Processing Units) and TPUs (Tensor Processing Units), where they may be essential for tasks such as graphics rendering and deep learning computations. They may also be implemented in SIMD (Single Instruction, Multiple Data) units within CPUs and GPUs, which may perform matrix operations by executing the same operation on multiple data points simultaneously. For highly specialized applications, matrix multipliers may also be incorporated into custom accelerators like FPGAs (Field-Programmable Gate Arrays) or ASICs (Application-Specific Integrated Circuits), which may be tailored for optimal performance in specific computational tasks.

The compute die (e.g., compute die 30) may be electrically coupled to the interposer layer (e.g., interposer layer 20) via one or more electrical connections positioned proximate the geometric center (to be discussed below in greater detail) of the one or more processing elements (e.g., processing elements 32). For example, the one or more electrical connections positioned proximate the geometric center (to be discussed below in greater detail) of the one or more processing elements (e.g., processing elements 32) may include: one or more power connections; and one or more ground connections. For example, the compute die (e.g., compute die 30) may be electrically coupled to the interposer layer (e.g., interposer layer 20) using one or more microbumps (e.g., microbumps 34, 36).

A microbump (e.g., microbumps 34, 36) is a small solder bump that may be used in semiconductor packaging to establish electrical connections between different layers in a 3D integrated circuit (IC) or between a chip and an interposer in a 2.5D IC. Microbumps are typically smaller than traditional solder bumps, which could enable higher interconnect density and facilitate advanced packaging techniques. In flip-chip technology, microbumps might be employed to attach a semiconductor die directly to a substrate or another die. This involves depositing microbumps on the bonding pads of the die and aligning them with corresponding pads on the substrate or the other die. Heating the assembly to reflow the solder could create a solid electrical and mechanical connection. Using microbumps might allow for greater miniaturization and integration of semiconductor devices, as they can enable more connections within a smaller area compared to traditional solder bumps. This could result in shorter signal paths, potentially enhancing signal speed and reducing power consumption. Microbumps may be essential for modern high-performance applications such as processors, memory modules, and advanced sensors, where maximizing performance while minimizing size is critical.

As discussed above, the compute die (e.g., compute die 30) may be electrically coupled to the interposer layer (e.g., interposer layer 20) via one or more electrical connections (e.g., microbumps 34, 36) positioned proximate the geometric center of the one or more processing elements (e.g., processing elements 32).

The Geometric Center (also known as the centroid) is a fundamental concept in geometry and physics. It serves as a crucial point of reference for understanding the distribution of mass or area within a shape. When considering a planar surface, envisioning it as a physical object of uniform density and thickness, the centroid represents the balance point where the surface could be perfectly balanced on a pivot. For simpler shapes like rectangles, circles, and triangles, the centroid is intuitively located at certain key points. In a rectangle, for instance, it's at the intersection of its diagonals, essentially the midpoint of the shape. Similarly, for circles and ellipses, it coincides with the center of symmetry due to their radial symmetry. In triangles, it's the intersection of the medians, which are lines drawn from each vertex to the midpoint of the opposite side, effectively dividing each median into segments of specific proportions. When dealing with irregular polygons, determining the centroid becomes more intricate. This involves considering the coordinates of the polygon's vertices and using mathematical formulas to calculate the centroid's position based on these coordinates and the area of the shape. By breaking down the polygon into triangles and computing the centroids of these constituent parts, the overall centroid of the polygon can be found by averaging these calculated centroids, weighted by the areas of the triangles.

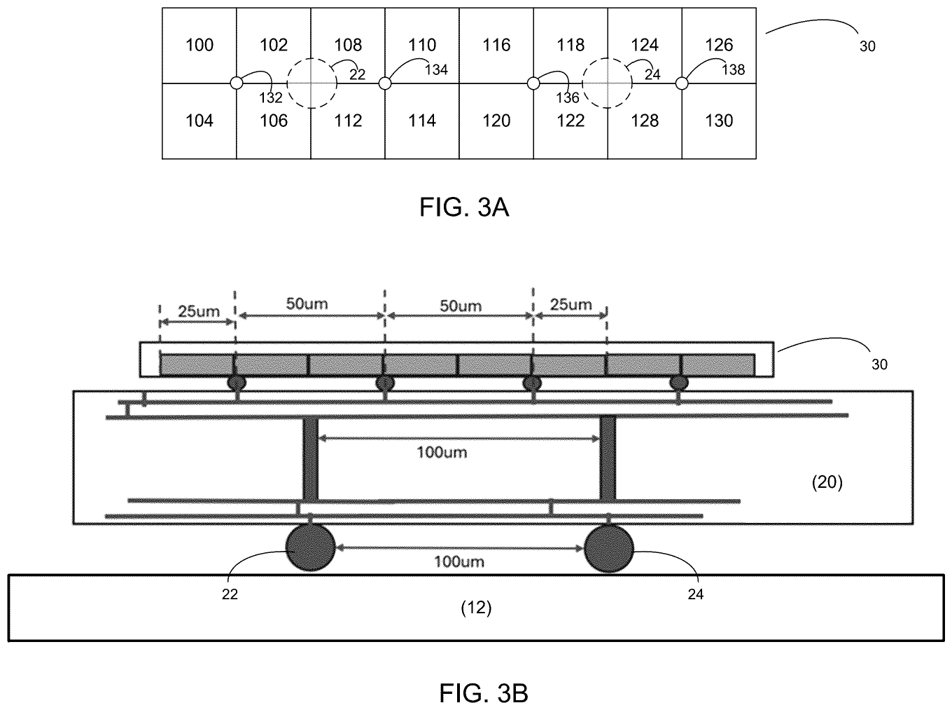

For example and referring also to FIGS. 3A & 3B, assume that the compute die (e.g., compute die 30) includes sixteen processing elements (e.g., processing elements 100, 102, 104, 106, 108, 110, 112, 114, 116, 118, 120, 122, 124, 126, 128, 130). The geometric center of these sixteen processing elements may vary depending upon the manner in which the processing elements are grouped and the quantity of electrical connections providing power to the processing elements.

For example and if only one electrical connection is providing power to the sixteen processing elements (e.g., processing elements 100, 102, 104, 106, 108, 110, 112, 114, 116, 118, 120, 122, 124, 126, 128, 130), these processing elements would be grouped into one group of sixteen processing elements (i.e., one 8×2 grid of processing elements). Accordingly, the geometric center of this group of sixteen processing elements may be at the intersection of processing elements 110, 114, 116, 120, as this is the geometric center of the 8×2 grid of processing elements.

However and if two electrical connections are providing power to the sixteen processing elements (e.g., processing elements 100, 102, 104, 106, 108, 110, 112, 114, 116, 118, 120, 122, 124, 126, 128, 130), these processing elements would be grouped into two groups of eight processing elements (i.e., two 4×2 grids of processing elements). Accordingly, the geometric centers of this group of sixteen processing elements may be at the intersection of processing elements 102, 106, 108, 112 and the intersection of processing elements 118, 122, 124, 128, as these are the geometric centers of these two 4×2 grids of processing elements.

Further and if four electrical connections are providing power to the sixteen processing elements (e.g., processing elements 100, 102, 104, 106, 108, 110, 112, 114, 116, 118, 120, 122, 124, 126, 128, 130), these processing elements would be grouped into four groups of four processing elements (i.e., four 2×2 grids of processing elements). Accordingly, the geometric centers of this group of sixteen processing elements may be at the intersection of processing elements 100, 104, 102, 106, the intersection of processing elements 108, 112, 110, 114, the intersection of processing elements 116, 120, 118, 122, and the intersection of processing elements 124, 128, 126, 130, as these are the geometric centers of these four 2×2 grids of processing elements.

Assume for this example that four electrical connections are providing power to the sixteen processing elements (e.g., processing elements 100, 102, 104, 106, 108, 110, 112, 114, 116, 118, 120, 122, 124, 126, 128, 130). Accordingly, four electrical connections (e.g., microbumps 132, 134, 136, 138) may be positioned at the four above-described geometric centers (namely the intersection of processing elements 100, 104, 102, 106, the intersection of processing elements 108, 112, 110, 114, the intersection of processing elements 116, 120, 118, 122, and the intersection of processing elements 124, 128, 126, 130).

Additionally, the dimensions of the processing elements (e.g., processing elements 100, 102, 104, 106, 108, 110, 112, 114, 116, 118, 120, 122, 124, 126, 128, 130) may be modified to match the distance between the electrical connections (e.g., microbumps 132, 134, 136, 138) so that the geometric center may still be maintained. Accordingly and once the location of the electrical connections (e.g., microbumps 132, 134, 136, 138) is determined, it may be easier to resize the processing elements (e.g., processing elements 100, 102, 104, 106, 108, 110, 112, 114, 116, 118, 120, 122, 124, 126, 128, 130) than to relocate the electrical connections (e.g., microbumps 132, 134, 136, 138). Alternatively and if it not desired to resize the processing elements (e.g., processing elements 100, 102, 104, 106, 108, 110, 112, 114, 116, 118, 120, 122, 124, 126, 128, 130), than the location of the electrical connections (e.g., microbumps 132, 134, 136, 138) may be modified.

As discussed above, interposer layer 20 may be electrically coupled to package layer 12 via one or more electrical connections positioned proximate the geometric center of one or more portions of the interposer layer (e.g., interposer layer 20).

For example, assume that two electrical connections (e.g., C4 bumps 22, 24) electrically couple interposer layer (e.g., interposer layer 20) and the package layer (e.g., package layer 12). Accordingly, interposer layer (e.g., interposer layer 20) may be divided into two portions (e.g., a left portion and a right portion in this illustrative example), wherein the geometric center of each of these two portions may be used to locate each of the two electrical connections (e.g., C4 bumps 22, 24). Positioning the two electrical connections (e.g., C4 bumps 22, 24) at the geometric center need not be limited to the above-described 3D IC configuration and may be applied to a monolithic (e.g., a system that includes a single die and a package) design as well.

The semiconductor package assembly (e.g., semiconductor package assembly 10) may be configured to utilize clock phasing to reduce peak current demand for the one or more processing elements (e.g., processing elements 32).

Clock Phasing: Clock phasing is a technique used in digital circuit design, particularly in integrated circuits (ICs), to manage signal propagation timing and control power consumption. It may involves introducing phase shifts or delays in clock signals to synchronize the operations of different circuit parts. Instead of having all sections of a circuit operate simultaneously on each clock edge, clock phasing may stagger their operations by using multiple clock phases or delayed clock signals, wherein the main clock signal is divided into several phases, each offset by a specific time, allowing different parts of the circuit to be triggered at different times. By staggering the switching times of different sections, clock phasing may reduce the number of transistors switching simultaneously, thereby decreasing peak current demand. When fewer transistors switch at once, the peak current drawn from the power supply may be lower, minimizing the risk of large current surges that can cause voltage drops and power supply noise. This even distribution of power demand over time may help maintain a more stable voltage level across the IC, enhancing its overall reliability and performance. Moreover, clock phasing may minimize power supply noise by spreading the power consumption more evenly, reducing the risk of noise affecting sensitive circuit elements. This may also aid in thermal management by preventing excessive simultaneous switching, which may lead to localized heating and potentially affect the IC's performance and longevity.

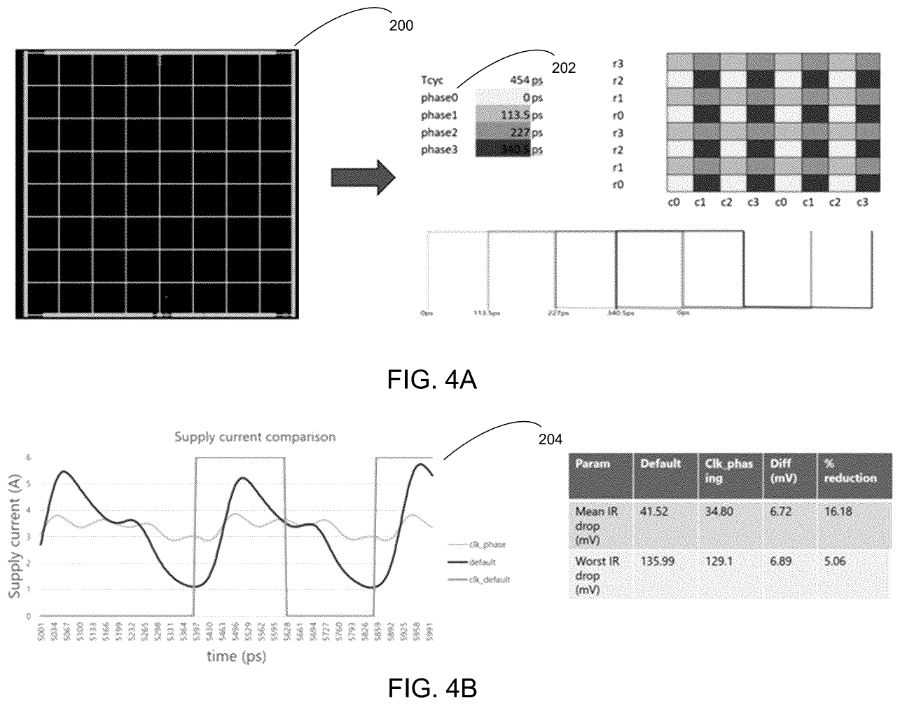

For example and referring also to FIGS. 4A & 4B, there is shown a visual example of the manner in which clock phasing reduces current surges. In this example, an 8×8 grid of processing elements (e.g., processing elements 200) is shown. Assume that clock phasing is utilized that results in four clock phases (e.g., clock phases 202), resulting on only sixteen processing elements switching in each of the four clock phases (as opposed to all sixty-four processing elements switching in a single clock phase), resulting in a dramatic smoothing of the current demand waveform (e.g., current demand waveform 204).

The semiconductor package assembly (e.g., semiconductor package assembly 10) may include a memory die (e.g., memory die 38) including one or more memory elements (e.g., memory elements 40, 42).

A Memory Die in the context of integrated circuits (ICs) (particularly in semiconductor manufacturing) may refer to a single silicon chip that contains memory cells. Memory dies are often produced in large quantities on a single silicon wafer during the semiconductor fabrication process. These dies are later cut or “diced” from the wafer and packaged into individual IC packages. Each memory die may contain a grid-like array of memory cells, which can store binary data as bits. The size of a memory die may vary depending upon the specific type of memory it contains, such as dynamic random-access memory (DRAM), static random-access memory (SRAM), flash memory, or other types. Memory dies may be used in a wide range of electronic devices, including computers, smartphones, tablets, and other consumer electronics.

Elements within a memory die may be the fundamental units responsible for storing digital information in electronic devices. These elements, organized into an array, may come in various forms depending on the memory technology used. In dynamic random-access memory (DRAM), for example, each memory cell may comprise a capacitor and a transistor, with the charge stored in the capacitor representing binary data. Contrastingly, static random-access memory (SRAM) cells may include of multiple transistors configured in a flip-flop circuit, allowing them to retain data without the need for periodic refreshing. Flash memory cells may employ floating gate transistors to store charge, making them non-volatile and suitable for applications requiring persistent storage. Additionally, phase-change memory (PCM) cells may utilize materials that can switch between amorphous and crystalline states to represent data, offering a balance between speed and non-volatility. Magnetic random-access memory (MRAM) cells may use magnetic fields to store data, providing fast read and write speeds along with non-volatility. Finally, ferroelectric RAM (FeRAM or FRAM) cells may leverage ferroelectric materials to align polarization for data storage, offering fast, non-destructive read and write operations.

The memory die (e.g., memory die 38) may be electrically coupled to the interposer layer (e.g., interposer layer 20) via one or more electrical connections positioned proximate the geometric center of the one or more memory elements (e.g., memory elements 40, 42). For example, the one or more electrical connections positioned proximate the geometric center of the one or more memory elements (e.g., memory elements 40, 42) may include: one or more power connections; and one or more ground connections. For example, the memory die (e.g., memory die 38) may be electrically coupled to the interposer layer (e.g., interposer layer 20) using one or more microbumps (e.g., microbump 44). The manner in which the one or more electrical connections may be positioned proximate the geometric center of the one or more memory elements (e.g., memory elements 40, 42) is similar to the manner in which the interposer layer 20 is electrically coupled to package layer 12 via one or more electrical connections (e.g., C4 bumps 22, 24) positioned proximate the geometric center of one or more portions of the interposer layer (e.g., interposer layer 20) and/or compute die 30 is electrically coupled to interposer layer 20 via one or more electrical connections (e.g., microbumps 34, 36) positioned proximate the geometric center of the one or more processing elements (e.g., processing elements 32).

### System Overview

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A semiconductor package assembly comprising:
a package layer;
an interposer layer electrically coupled to the package layer; and
a compute die including one or more processing elements, wherein the compute die is electrically coupled to the interposer layer via one or more electrical connections positioned proximate the geometric center of the one or more processing elements.

2. The semiconductor package assembly of claim 1 wherein the semiconductor package assembly is configured to utilize clock phasing to reduce peak current demand for the one or more processing elements.

3. The semiconductor package assembly of claim 1 wherein the one or more processing elements includes:
one or more matrix multipliers.

4. The semiconductor package assembly of claim 1 wherein the one or more electrical connections positioned proximate the geometric center of the one or more processing elements includes:
one or more power connections; and
one or more ground connections.

5. The semiconductor package assembly of claim 1 further comprising:
a memory die including one or more memory elements.

6. The semiconductor package assembly of claim 5 wherein the memory die is electrically coupled to the interposer layer via one or more electrical connections positioned proximate the geometric center of the one or more memory elements.

7. The semiconductor package assembly of claim 6 wherein the one or more electrical connections positioned proximate the geometric center of the one or more memory elements includes:
one or more power connections; and
one or more ground connections.

8. The semiconductor package assembly of claim 1 wherein the interposer layer is electrically coupled to the package layer via one or more electrical connections positioned proximate the geometric center of one or more portions of the interposer layer.

9. The semiconductor package assembly of claim 8 wherein the one or more electrical connections positioned proximate the geometric center of one or more portions of the interposer layer includes:
one or more power connections; and
one or more ground connections.

10. The semiconductor package assembly of claim 1 wherein the interposer layer includes:
one or more interposer ReDistribution Layers and one or more Through Silicon Vias to distribute power to the compute die.

11. The semiconductor package assembly of claim 1 wherein the package layer is configured to be electrically coupled to a system board.

12. A semiconductor package assembly comprising:
a package layer;
an interposer layer electrically coupled to the package layer; and
a compute die including one or more processing elements, wherein the compute die is electrically coupled to the interposer layer via one or more electrical connections positioned proximate the geometric center of the one or more processing elements;
wherein the semiconductor package assembly is configured to utilize clock phasing to reduce peak current demand for the one or more processing elements.

13. The semiconductor package assembly of claim 12 wherein the one or more processing elements includes:
one or more matrix multipliers.

14. The semiconductor package assembly of claim 12 further comprising:
a memory die including one or more memory elements.

15. The semiconductor package assembly of claim 12 wherein the interposer layer is electrically coupled to the package layer via one or more electrical connections positioned proximate the geometric center of one or more portions of the interposer layer.

16. The semiconductor package assembly of claim 12 wherein the interposer layer includes:
one or more interposer ReDistribution Layers and one or more Through Silicon Vias to distribute power to the compute die.

17. The semiconductor package assembly of claim 12 wherein the package layer is configured to be electrically coupled to a system board.

18. A semiconductor package assembly comprising:
a package layer;
an interposer layer electrically coupled to the package layer; and
a compute die including one or more processing elements, wherein the compute die is electrically coupled to the interposer layer via one or more electrical connections positioned proximate the geometric center of the one or more processing elements;
wherein the one or more processing elements includes: one or more matrix multipliers.

19. The semiconductor package assembly of claim 18 wherein the semiconductor package assembly is configured to utilize clock phasing to reduce peak current demand for the one or more processing elements.

20. The semiconductor package assembly of claim 18 further comprising:
a memory die including one or more memory elements.
